(19) United States
(12) Patent Application Publication
(10) Pub. No.: US 2015/0016584 A1
(43) Pub. Date: Jan. 15, 2015

(54) SHIFT REGISTER UNIT, DISPLAY PANEL AND DISPLAY DEVICE

(71) Applicants: Tianma Micro-Electronics Co., Ltd., Shenzhen (CN); Shanghai AVIC Optoelectronics Co., Ltd., Shanghai (CN)

(72) Inventors: Dongliang DUN, Shanghai (CN); Zhiqiang XIA, Shanghai (CN)

(73) Assignees: Tianma Micro-Electronics Co., Ltd., Shenzhen (CN); Shanghai AVIC Optoelectronics Co., Ltd., Shanghai (CN)

(21) Appl. No.: 14/226,760

(22) Filed: Mar. 26, 2014

(30) Foreign Application Priority Data
Jul. 11, 2013 (CN) 201310292248.5

(51) Int. Cl. G11C 27/04

(52) U.S. Cl. CPC G11C 27/04
USPC 377/68

(57) ABSTRACT

A shift register unit, a display panel including the shift register unit and a display device including the display panel are provided. The shift register unit includes a driving module, an output module, a first transistor, and a second transistor. By connecting a second electrode of the first transistor in the shift register unit with an output terminal of the shift register unit, even if a channel width of the second transistor is considerably smaller than a theoretical design value, abnormal output of the shift register unit can be avoided.

### CROSS-REFERENCES TO RELATED APPLICATIONS

This application claims the benefit of priority to Chinese Patent Application No. 201310292248.5, filed with the Chinese Patent Office on Jul. 11, 2013 and entitled “SHIFT REGISTER UNIT, DISPLAY PANEL AND DISPLAY DEVICE”, the content of which is incorporated herein by reference in its entirety.

### BACKGROUND OF THE INVENTION

1. Field

The present invention relates to the field of display technologies, and more particularly to a shift register unit, a display panel and a display device.

2. Background

Liquid Crystal Displays (LCDs) or Organic Light-Emitting Diodes (OLEDs) display with the advantages of low radiation, small size, low energy consumption and light-weight have gradually replaced traditional Cathode Ray Tube displays (CRTs) in many applications, for example in information products such as notebook computers, Personal Digital Assistants (PDAs), flat-screen televisions and mobile phones. A traditional liquid crystal display displays pictures using an external driver chip driving a chip on a panel. In order to reduce the number of elements and lower the manufacturing cost, a driver circuit structure is directly manufactured on the display panel in recent years, for example, a Gate On Array (GOA) technology of integrating a gate driver on a liquid crystal panel is adopted.

The typical structure of an existing shift register unit is shown in FIG. 1, wherein VGL is a low voltage signal, and transistors T0, T1, T2, T3, T4, T5, and T6 are amorphous silicon transistors, i.e., n-type transistors. If V1 is a high level signal and V2 is a low level signal, and when a previous shift register unit outputs a high level signal, i.e., OUT (n−1) is a high level signal, and a clock blocking signal (CLKB) is a low level signal, the transistor T0 is turned on, a node P is a high level signal, both the transistor T3 and the transistor T4 are turned on, and the shift register unit outputs a low level signal, i.e., OUT (n) is a low level signal. When the CLKB is a high level signal, potential of a node Q quickly rises when the CLKB becomes a high level signal, and then declines from high to low potential due to the turn-on of the transistor T3, that is the potential of the node Q is subjected to a process of being quickly pulled down to the VGL after the quick rise. Since the transistor T2 is turned on under an influence of the node Q and the turn-on of the transistor T2 further achieves a pull-down effect on the potential of the node P, thus the output voltage of the OUT (n) is affected. When the channel width of the transistor T3 approaches a theoretical design value, for example, when the channel width of the transistor T3 is 340 μm which is a theoretical design value, the potential of the node Q is quickly pulled down to VGL as shown in FIG. 2 (indicated as in the dotted ellipse in FIG. 2), thus the transistor T2 is turned on for a very short time, which leads no influence on the potential of the node P. At this time, although the OUT (n−1) is not outputted a high level signal any more, the node P is still kept at a high level and the transistor T4 is kept on due to the storage effect of a capacitor C2, thus the shift register unit outputs a high level signal, i.e., the OUT (n) is a high level signal. The potential of the node P rises again due to the bootstrap effect of the capacitor C2, so that the driving capability of the transistor T4 is relatively strong, thus ensuring that the OUT (n) can be quickly changed from a low level to a high level.

When the channel width of the transistor T3 is far from the theoretical design value, for example, when the channel width of the transistor T3 is 20 μm while the theoretical design value is 340 μm, the discharge capability of the transistor T3 is limited due to the limitation of the channel width of the transistor T3, and the pull-down time of the potential of the node Q is greatly prolonged as shown in FIG. 3 (indicated as the solid ellipse in FIG. 3) compared with the pull-down time of the potential of the node Q in FIG. 2, thus the turn-on time of the transistor T2 is prolonged, resulting in that the potential of the node P cannot rise again (the part in the dotted ellipse in FIG. 3), and the potential of the node P is not high enough. Because the potential of the node P is the potential of a gate of the transistor T4, the driving capability of the transistor T4 is relatively poor, thus the time for the signal outputted by the shift register unit to turn from a low level to a high level is relatively long when the CLKB is changed from the low level signal to a high level signal, i.e., the signal output of OUT (n) is abnormal (the part in the solid circle in FIG. 3).

In view of the above, when the structure of the existing shift register unit is adopted, the transistors in the shift register unit are the amorphous silicon transistors. If the channel width of the transistor T3 is far smaller than the theoretical design value, the turn-on time of the transistor T2 will be prolonged, causing the potential of the node P cannot rise again, thus the output signal of the shift register unit will be abnormal.

### BRIEF SUMMARY OF THE INVENTION

In view of this, a shift register unit provided in an embodiment of the invention includes a driving module, an output module, a first transistor and a second transistor.

A first port of the driving module receives a positive selection signal, a second port of the driving module receives a first level signal, a third port of the driving module receives a reverse selection signal, a fourth port of the driving module receives a second level signal, a fifth port of the driving module receives a low voltage signal, a sixth port of the driving module is connected with a gate of the first transistor and a first electrode of the second transistor, a seventh port of the driving module is connected with a third port of the output module, an eighth port of the driving module is connected with a first electrode of the first transistor, a gate of the second transistor and a first port of the output module at a connecting node being a pull-up node, a ninth port of the driving module receives a clock blocking signal, a tenth port of the driving module receives a clock signal, a second electrode of the first transistor is connected with the third port of the output module, a second electrode of the second transistor receives the low voltage signal, a second port of the output module receives the clock blocking signal, and the third port of the output module serves as an output terminal of the shift register unit.

The driving module is configured to output the first level signal through its eighth port when the positive selection signal is at a logic high level and the clock blocking signal is at a logic low level, and to output the second level signal through its eighth port when the reverse selection signal is at the logic high level and the clock blocking signal is at the logic low level, and to output the low voltage signal through its seventh port when the clock signal is at the logic high level, and to output the clock blocking signal through its sixth port, and to output the low voltage signal through its seventh port when the signal of the first electrode of the second transistor is at the logic high level.

The output module is configured to output the clock blocking signal through its third port when the pull-up node is at the turn-on level (e.g. the potential of the pull-up node PU is a high level), and stops outputting the clock blocking signal any more when the pull-up node is at the turn-off level (e.g. the potential of the pull-up node PU is a low level).

The first transistor is configured to connect the pull-up node with the output terminal of the shift register unit when the first electrode of the second transistor is at the logic high level, and disconnect the pull-up node from the output terminal of the shift register unit when the first electrode of the second transistor is at the logic low level.

The second transistor is configured to control the signal of its first electrode to be the low voltage signal when the pull-up node is at the turn-on level (e.g. the potential of the pull-up node PU is a high level), and be turned off when the pull-up node is at the turn-off level (e.g. the potential of the pull-up node PU is a low level).

An embodiment of the invention further provides a display panel, including the shift register unit provided in the embodiments of the invention.

An embodiment of the invention further provides a display device, including the display panel provided in the embodiments of the invention.

According to the shift register unit, the display panel and the display device provided in the embodiments of the invention, because the driving module may output the clock blocking signal through its sixth port, when the signal of the pull-up node, i.e., the signal of the gate of the second transistor, is a high level signal and the clock blocking signal is changed from a low level signal to a high level signal, the potential of the first electrode of the second transistor connected with the sixth port of the driving module is quickly changed to a high level first, and then the level of the first electrode of the second transistor is changed from a high level to a low level as shown in FIG. 4, (the part in the solid ellipse in FIG. 4) due to the turn-on of the second transistor; Therefore, the level of the first electrode of the second transistor is subjected to a process of being quickly pulled down to a low level after a quick rise, accordingly, the level of the gate of the first transistor connected with the first electrode of the second transistor is subjected to a process of being quickly pulled down to a low level after a quick rise, i.e., the first transistor has a process of turn-on and then turn-off; the first electrode of the first transistor is connected with the pull-up node and the second electrode of the first transistor is connected with the output terminal of the shift register unit, therefore the turn-on of the first transistor may lead to the connection between the pull-up node and the output terminal of the shift register unit. When both the signal of the pull-up node and the clock blocking signal are high level signals, the output terminal of the shift register unit will output a high level signal; that is, even if the first transistor is turned on, a pull-down effect (the part in the dotted ellipse in FIG. 4) will not be produced on the high level of the pull-up node, the problem that the output of the shift register unit is abnormal (the part in the solid circle in FIG. 4) because the potential of the pull-up node cannot rise again is solved.

### BRIEF DESCRIPTION OF THE DRAWINGS

FIG. 1 is a schematic diagram of a structure of a shift register unit in the prior art;

FIG. 2 is a diagram of a time sequence that the shift register unit receives and outputs signals when the shift register unit in the prior art is adopted and a channel width of a transistor T3 is equal to a theoretical design value;

FIG. 3 is a diagram of a time sequence that the shift register unit receives and outputs signals when the shift register unit in the prior art is adopted and the channel width of the transistor T3 is considerably smaller than the theoretical design value;

FIG. 4 is a diagram of a time sequence that a shift register unit receives and outputs signals when the shift register unit provided in an embodiment of the invention is adopted and a channel width of the transistor T3 is considerably smaller than the theoretical design value;

FIG. 5 is a schematic diagram of a structure of a shift register unit according to an embodiment of the invention;

FIG. 6 is a schematic diagram of a structure of a shift register unit according to another embodiment of the invention;

FIG. 7 is a schematic diagram of a structure of a shift register unit according to another embodiment of the invention;

FIG. 8 is a schematic diagram of a structure of a shift register unit according to another embodiment of the invention;

FIG. 9 is a schematic diagram of a structure of a shift register unit according to another embodiment of the invention;

FIG. 10 is a schematic diagram of a structure of a shift register unit according to another embodiment of the invention;

FIG. 11 is a schematic diagram of a structure of a shift register unit according to another embodiment of the invention;

FIG. 12 is a schematic diagram of a structure of a shift register unit according to another embodiment of the invention;

FIG. 13 is an operating time sequence diagram during a positive scanning period of a shift register unit provided in another embodiment of the invention; and

FIG. 14 is an operating time sequence diagram during a reverse scanning period of a shift register unit according to another embodiment of the invention.

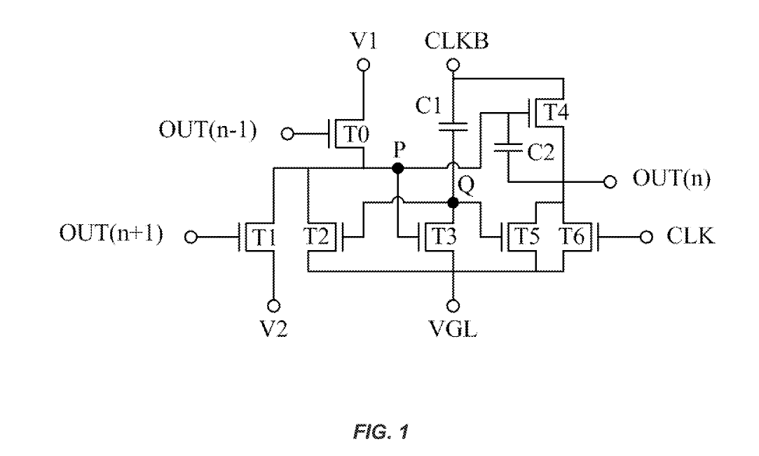

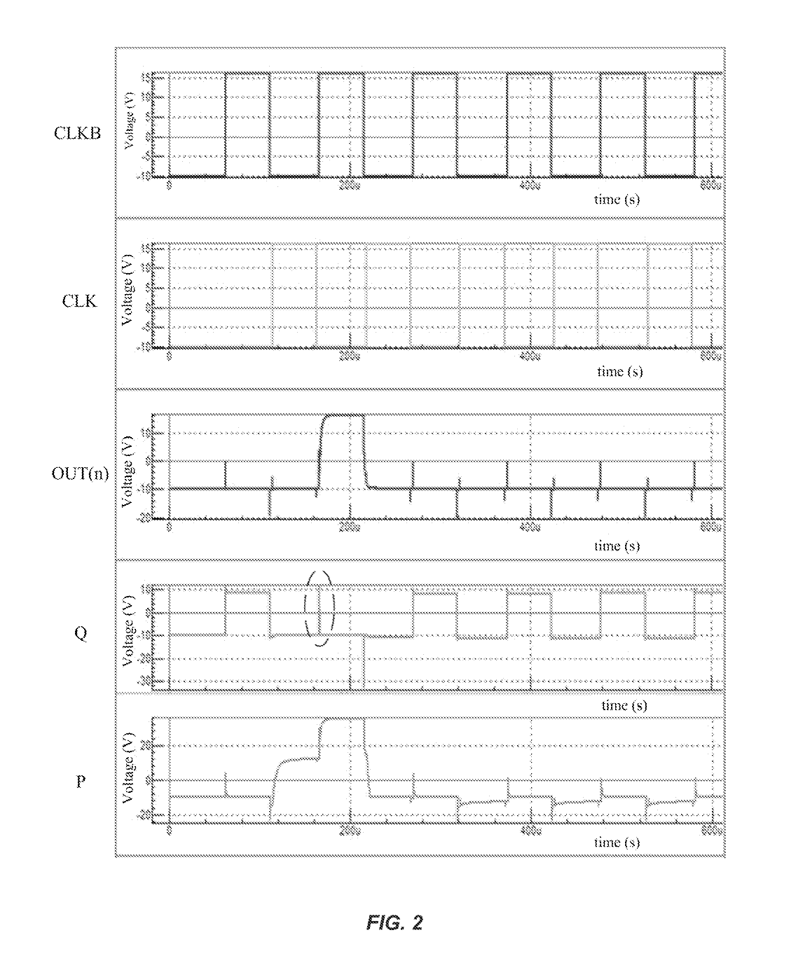

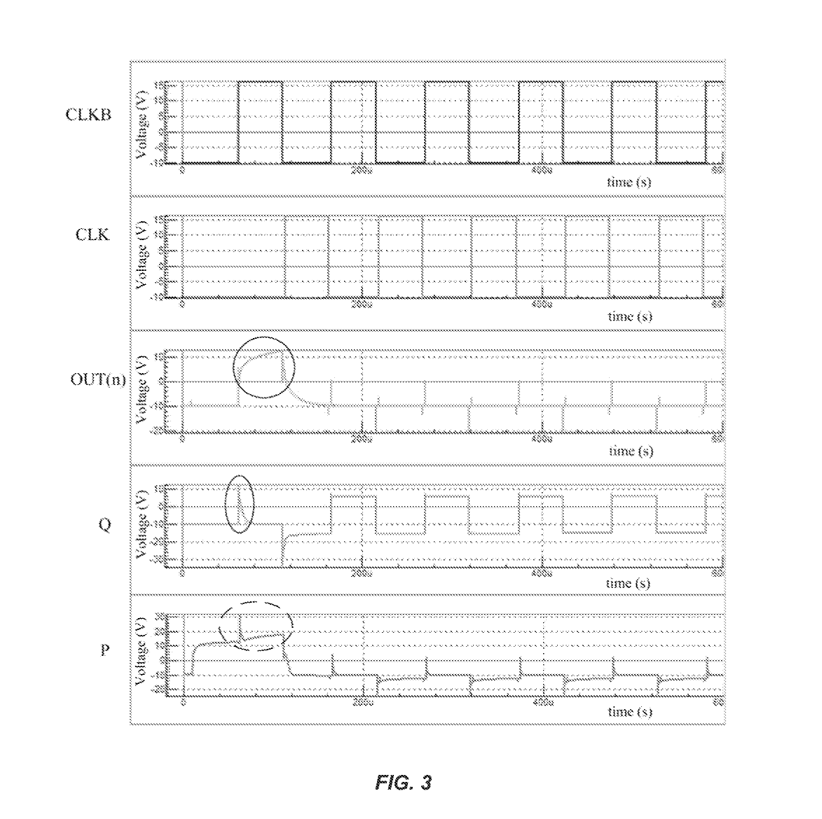

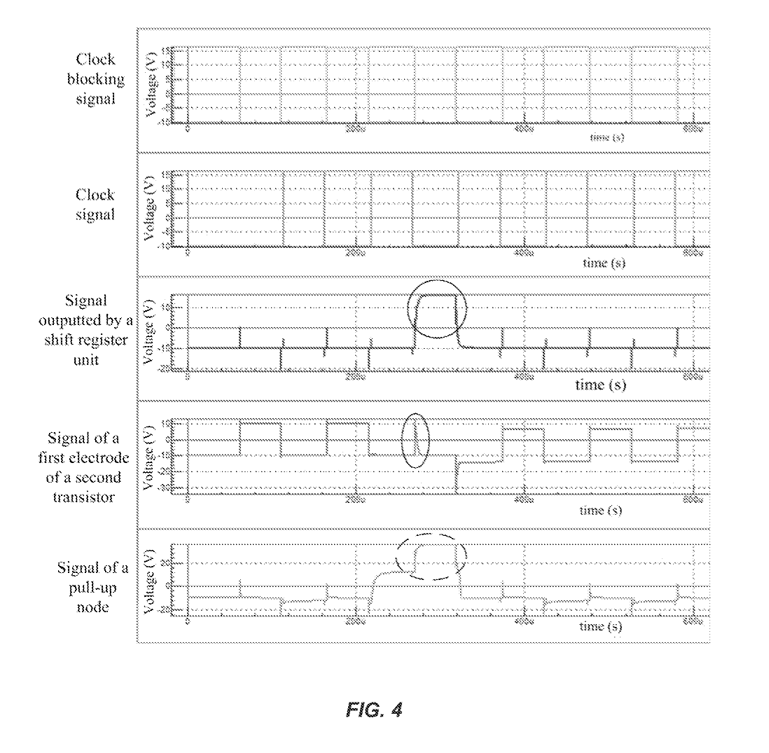

### DETAILED DESCRIPTION OF THE INVENTION

In embodiments of the invention, a shift register unit, a display panel and a display device are provided for avoiding abnormal output of the shift register unit through connecting a second electrode of a first transistor in the shift register unit with the output terminal of the shift register unit, even if a channel width of a second transistor is far smaller than a theoretical design value.

Specific implementations of the shift register unit, the display panel and the display device provided in the embodiments of the invention are illustrated below with reference to the accompanying drawings.

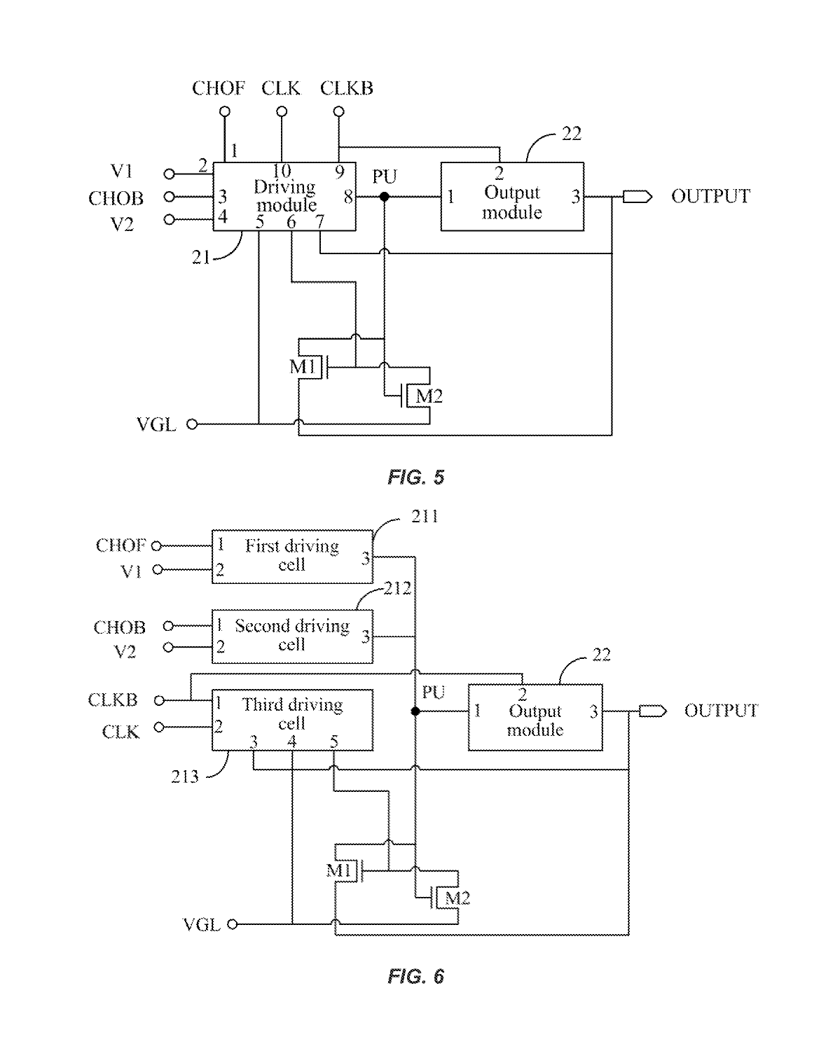

A shift register unit provided in an embodiment of the invention, as shown in FIG. 5, includes a driving module 21, an output module 22, a first transistor M1 and a second transistor M2.

A first port 1 of the driving module 21 receives a positive selection signal CHOF, a second port 2 of the driving module 21 receives a first level signal V1, a third port 3 of the driving module 21 receives a reverse selection signal CHOB, a fourth port 4 of the driving module 21 receives a second level signal V2, a fifth port 5 of the driving module 21 receives a low voltage signal VGL, a sixth port 6 of the driving module 21 is connected with a gate of the first transistor M1 and a first electrode of the second transistor M2, a seventh port 7 of the driving module 21 is connected with a third port 3 of the output module 22, an eighth port 8 of the driving module 21 is connected with a first electrode of the first transistor M1, a gate of the second transistor M2 and a first port 1 of the output module 22 at a connecting node being a pull-up node PU, a ninth port 9 of the driving module 21 receives a clock blocking signal CLKB, and a tenth port 10 of the driving module 21 receives a clock signal CLK. A second electrode of the first transistor M1 is connected with the third port 3 of the output module 22, a second electrode of the second transistor M2 receives the low voltage signal VGL, a second port 2 of the output module 22 receives the clock blocking signal CLKB, and the third port 3 of the output module 22 serves as an output terminal OUTPUT of the shift register unit.

The driving module 21 is configured to output the first level signal V1 through its eighth port 8 when the positive selection signal CHOF is a high level signal and the clock blocking signal CLKB is a low level signal, that is, the signal of the pull-up node PU is the first level signal; and to output the second level signal V2 through its eighth port 8 when the reverse selection signal CHOB is a high level signal and the clock blocking signal CLKB is the low level signal, that is, the signal of the pull-up node PU is the second level signal; and to connect its fifth port 5 with its seventh port 7 when the clock signal CLK is a high level signal, so as to output the low voltage signal VGL received by its fifth port 5 through its seventh port 7; and to output the clock blocking signal CLKB received by its ninth port 9 through its sixth port 6; and to connect its fifth port 5 with its seventh port 7 when the signal of the first electrode of the second transistor M2 is a high level signal, so as to output the low voltage signal VGL received by its fifth port 5 through its seventh port 7.

The output module 22 is configured to connect its second port 2 with its third port 3 when the potential of the pull-up node PU is high, i.e., the pull-up node PU is at the turn-on level, so as to output the clock blocking signal CLKB received by its second port 2 through its third port 3; and to disconnect its second port 2 from its third port 3 when the potential of the pull-up node PU is low, i.e., the pull-up node PU is at the turn-off level, so as not to output the clock blocking signal CLKB received by its second port 2 through its third port 3.

The first transistor M1 is configured to be turned on when the signal of the first electrode of the second transistor M2 is a high level signal so as to connect the pull-up node PU with the output terminal OUTPUT of the shift register unit; and to be turned off when the level of the first electrode of the second transistor M2 is low so as to disconnect the pull-up node PU from the output terminal OUTPUT of the shift register unit.

The second transistor M2 is configured to be turned on when the pull-up node PU is at the turn-on level (e.g. the potential of the pull-up node PU is a high level) to control the signal of its first electrode to be the low voltage signal VGL, and to be turned off when the pull-up node PU is at the turn-off level (e.g. the potential of the pull-up node PU is a low level).

Further, with reference to FIG. 5 and FIG. 6, the driving module in the shift register unit provided in another embodiment of the invention includes a first driving cell 211, a second driving cell 212 and a third driving cell 213.

A first port 1 of the first driving cell 211 is the first port 1 of the driving module 21, a second port 2 of the first driving cell 211 is the second port 2 of the driving module 21, a third port 3 of the first driving cell 211 and a third port 3 of the second driving cell 212 are the eighth port 8 of the driving module 21, a first port 1 of the second driving cell 212 is the third port 3 of the driving module 21, a second port 2 of the second driving cell 212 is the fourth port 4 of the driving module 21, a first port 1 of the third driving cell 213 is the ninth port 9 of the driving module 21, a second port 2 of the third driving cell 213 is the tenth port 10 of the driving module 21, a third port 3 of the third driving cell 213 is the seventh port 7 of the driving module 21, a fourth port 4 of the third driving cell 213 is the fifth port 5 of the driving module 21, and a fifth port 5 of the third driving cell 213 is the sixth port 6 of the driving module 21.

The first driving cell 211 is configured to output the first level signal V1 received by its second port 2 through its third port 3 when the positive selection signal CHOF is a high level signal.

The second driving cell 212 is configured to output the second level signal V2 received by its second port 2 through its third port 3 when the reverse selection signal CHOB is a high level signal.

The third driving cell 213 is configured to connect its fourth port 4 with its third port 3 when the clock signal CLK is a high level signal, so as to output the low voltage signal VGL received by its fourth port 4 through its third port 3; and to output the clock blocking signal CLKB received by its first port 1 through its fifth port 5; and to connect its fourth port 4 with its third port 3 when the signal of the first electrode of the second transistor M2 is a high level signal, so as to output the low voltage signal VGL received by its fourth port 4 through its third port 3.

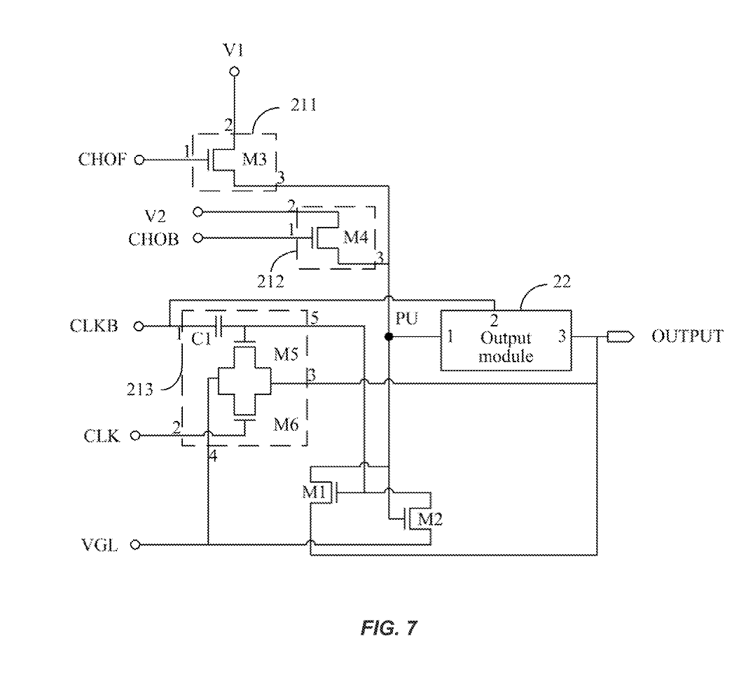

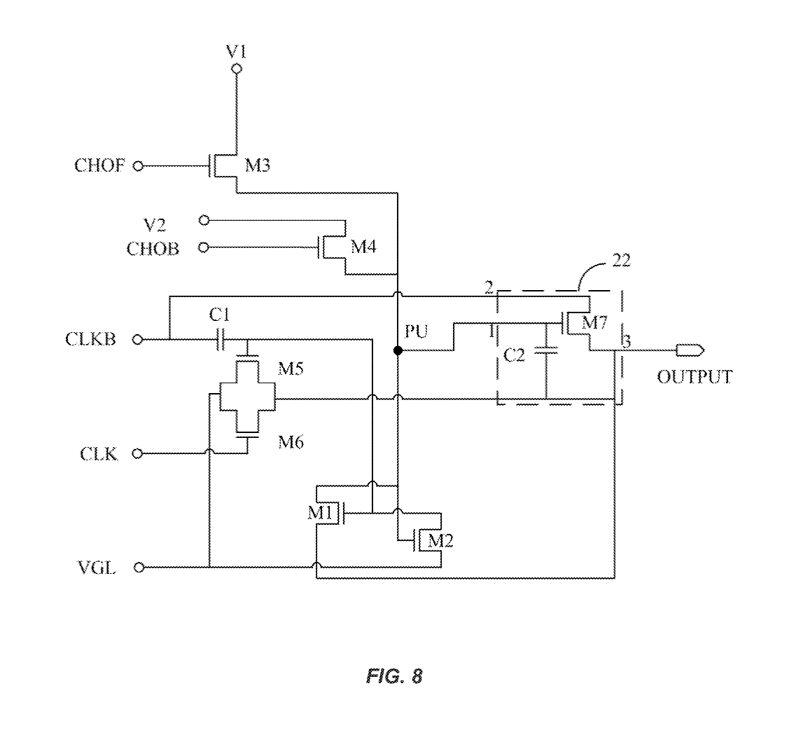

Further, with reference to FIG. 6 and FIG. 7, the first driving cell in the shift register unit provided in another embodiment of the invention can further include a third transistor M3. A gate of the third transistor M3 is the first port 1 of the first driving cell 211, a first electrode of the third transistor M3 is the second port 2 of the first driving cell 211, and a second electrode of the third transistor M3 is the third port 3 of the first driving cell 211. The third transistor M3 is configured to be turned on when the positive selection signal CHOF is a high level signal so that the signal of the pull-up node PU is the first level signal V1 and to be turned off when the positive selection signal CHOF is a low level signal.

Further, with reference to FIG. 6 and FIG. 7, the second driving cell 212 in the shift register unit provided in another embodiment of the invention can further include a fourth transistor M4. A gate of the fourth transistor M4 is the first port 1 of the second driving cell 212, a first electrode of the fourth transistor M4 is the second port 2 of the second driving cell 212, and a second electrode of the fourth transistor M4 is the third port 3 of the second driving cell 212. The fourth transistor M4 is configured to be turned on when the reverse selection signal CHOB is a high level signal, so that the signal of the pull-up node PU is the second level signal V2 and to be turned off when the reverse selection signal CHOB is a low level signal.

Further, with reference to FIG. 6 and FIG. 7, the third driving cell in the shift register unit provided in another embodiment of the invention can further include a first capacitor C1, a fifth transistor M5 and a sixth transistor M6.

One terminal of the first capacitor C1 is the first port 1 of the third driving cell 213, the other terminal of the first capacitor C1 and a gate of the fifth transistor M5 are the fifth port 5 of the third driving cell 213, a first electrode of the fifth transistor M5 and a first electrode of the sixth transistor M6 are the third port 3 of the third driving cell 213, a second electrode of the fifth transistor M5 and a second electrode of the sixth transistor M6 are the fourth port 4 of the third driving cell 213, and a gate of the sixth transistor M6 is the second port 2 of the third driving cell 213.

The first capacitor C1 is configured to couple the received clock blocking signal CLKB to the first electrode of the second transistor M2.

The fifth transistor M5 is configured to be turned on when the level of the first electrode of the second transistor M2 is high so as to control the output terminal OUTPUT of the shift register unit to output the low voltage signal VGL, and to be turned off when the level of the first electrode of the second transistor M2 is low.

The sixth transistor M6 is configured to be turned on when the clock signal CLK is a high level signal so as to control the output terminal OUTPUT of the shift register unit to output the low voltage signal VGL, and to be turned off when the clock signal CLK is a low level signal.

Further, with reference to FIG. 7 and FIG. 8, the output module in the shift register unit provided in another embodiment of the invention may include a second capacitor C2 and a seventh transistor M7. One terminal of the second capacitor C2 and a gate of the seventh transistor M7 are the first port 1 of the output module 22, the other terminal of the second capacitor C2 and a second electrode of the seventh transistor M7 are the third port 3 of the output module 22, and a first electrode of the seventh transistor M7 is the second port 2 of the output module 22. The second capacitor C2 is configured to store the voltage signal of the pull-up node PU; and the seventh transistor M7 is configured to be turned on when the potential of the pull-up node PU is high (i.e., the pull-up PU is at the turn-on level) so as to output the received clock blocking signal CLKB, and to be turned off when the potential of the pull-up node PU is low (i.e., the pull-up node PU is at the turn-off level) so as not to output the received clock blocking signal CLKB any more.

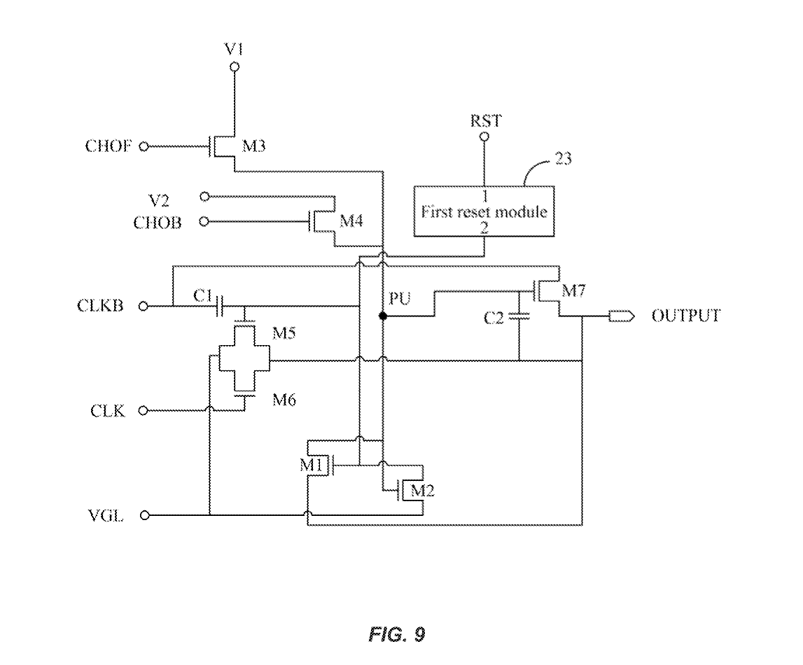

Further, as shown in FIG. 9, the shift register unit provided in another embodiment of the invention may also include a first reset module 23. A first port 1 of the first reset module 23 receives a reset signal RST, and a second port 2 of the first reset module 23 is connected with the first electrode of the second transistor M2; and the first reset module 23 is configured to output the reset signal RST received by its first port 1 through its second port 2 when the reset signal RST is a high level signal.

After the first reset module is added in the shift register unit provided in the embodiments of the invention, the reset signal RST may be set as a high level signal for a certain period of time before each frame starts, so that the second port of the first reset module outputs a high level signal, that is, the signals of the gates of both the first transistor M1 and the fifth transistor M5 are high level signals, thus both the first transistor M1 and the fifth transistor M5 are turned on, the signal of the output terminal OUTPUT of the shift register unit is the low voltage signal VGL due to the turn-on of the fifth transistor M5, the pull-up node PU is connected with the output terminal OUTPUT of the shift register unit due to the turn-on of the first transistor M1, i.e., the signal of the pull-up node PU is the low voltage signal VGL. In this way, the level of the pull-up node PU may be set as a low level before each frame starts, and the level of a gate line connected with the shift register unit may be set as a low level, to avoid the influence on signals of a next frame resulting from signals which may not be emptied and probably left on the pull-up node and the a gate line connected with the shift register unit when the shift register unit outputs the signals in a previous frame, and if the reset signal is set as a high level signal for a certain period of time during turn-on of a computer, the problem of a blurred screen in turn-on may be solved.

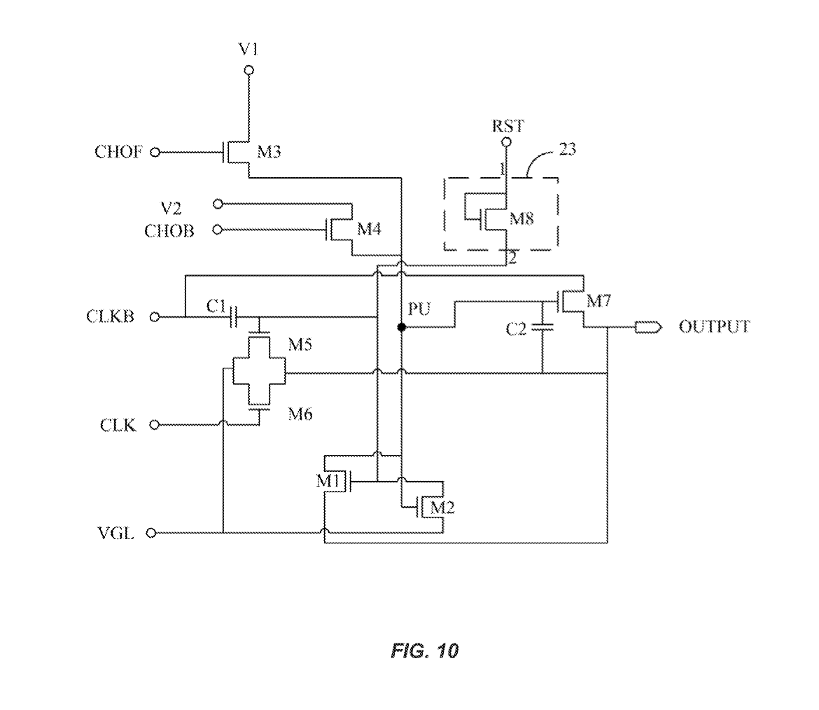

Further, as shown in FIG. 9 and FIG. 10, the first reset module in the shift register unit provided in another embodiment of the invention can further include an eighth transistor M8. Both a gate and a first electrode of the eighth transistor M8 are the first port 1 of the first reset module 23, and a second electrode of the eighth transistor M8 is the second port 2 of the first reset module 23; and the eighth transistor M8 is configured to be turned on when the reset signal RST is a high level signal and to be turned off when the reset signal RST is a low level signal.

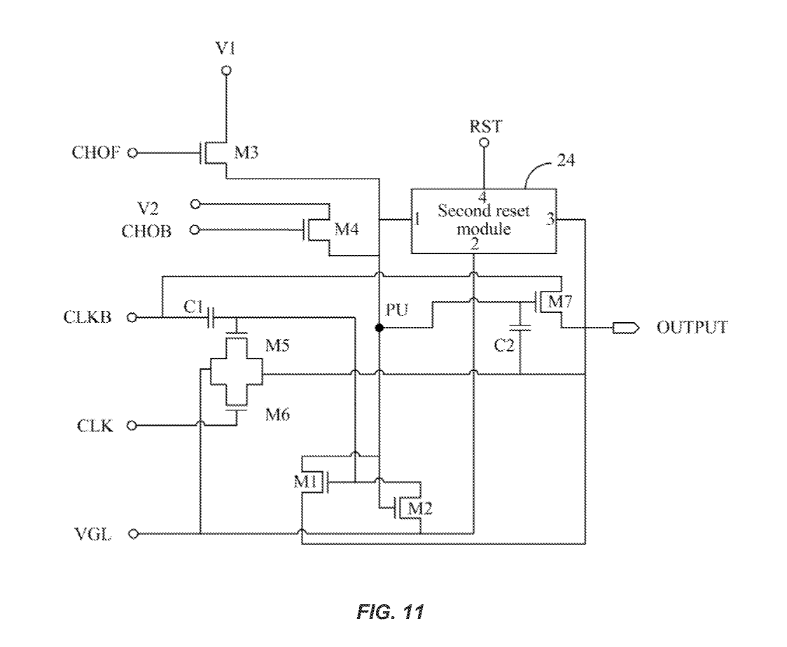

Further, as shown in FIG. 11, the shift register unit provided in another embodiment of the invention may also include a second reset module 24. A first port 1 of the second reset module 24 is connected with the pull-up node PU, a second port 2 of the second reset module 24 receives the low voltage signal VGL, a third port 3 of the second reset module 24 is connected with the output terminal OUTPUT of the shift register unit, and a fourth port 4 of the second reset module 24 receives a reset signal RST; and the second reset module 24 is configured to connect its first port 1 with its second port 2 and connect its third port 3 with its second port 2 when the reset signal RST is a high level signal, so that its first port 1 and its third port 3 output the low voltage signal VGL.

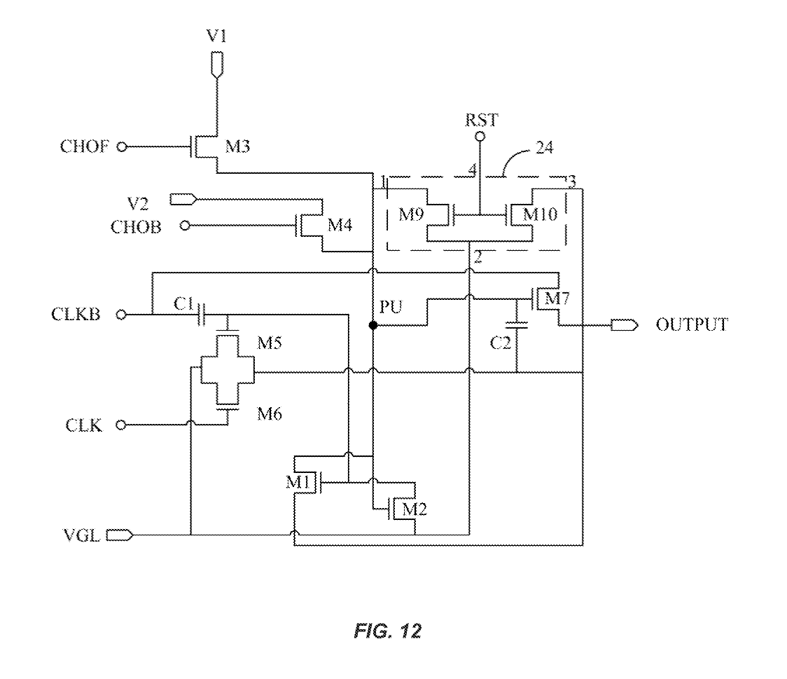

Further, as shown in FIG. 11 and FIG. 12, the second reset module in the shift register unit provided in another embodiment of the invention may further include a ninth transistor M9 and a tenth transistor M10. Gates of both the ninth transistor M9 and the tenth transistor M10 are the fourth port 4 of the second reset module 24, a first electrode of the ninth transistor M9 is the first port 1 of the second reset module 24, second electrodes of both the ninth transistor M9 and the tenth transistor M10 are the second port 2 of the second reset module 24, and a first electrode of the tenth transistor M10 is the third port 3 of the second reset module 24. The ninth transistor M9 is configured to be turned on when the reset signal RST is a high level signal, so that the signal of the pull-up node PU is the low voltage signal VGL and to be turned off when the reset signal RST is a low level signal; and the tenth transistor M10 is configured to be turned on when the reset signal RST is a high level signal, so that the signal of the output terminal OUTPUT of the shift register unit is the low voltage signal VGL and to be turned off when the reset signal RST is a low level signal.

After the second reset module is added in the shift register unit provided in the embodiments of the invention, the reset signal RST may be set as a high level signal for a certain period of time before each frame starts, so that both the first port and the third port of the second reset module output the low voltage signal VGL, that is, the level of the pull-up node PU is a low level, and the level of the output terminal OUTPUT of the shift register unit is a low level, in this way, the level of the pull-up node PU may be set as a low level before each frame starts, and further the level of a gate line connected with the shift register unit will be set as a low level, thus to avoid the influence on signals of a next frame resulting from signals which may not be emptied and probably left on the pull-up node and a gate line connected with the shift register unit when the shift register unit outputs the signals in a previous frame; and if the reset signal is set as a high level signal for a certain period of time during turn-on of a computer, the problem of a blurred screen in turn-on may be solved.

For each transistor in the field of liquid crystal displays, a drain and a source are not definitely distinguished, so a first electrode of each transistor referred in the embodiments of the invention may be a source (or drain) of the transistor, and a second electrode of the transistor may be a drain (or source) of the transistor. If a source of the transistor is the first electrode, then a drain of the transistor is the second electrode; and if the drain of the transistor is the first electrode, then the source of the transistor is the second electrode.

When a shift register including the shift register units according to the embodiments of the invention performs a positive scanning, the first level signal received by each shift register unit is a high level signal, and the second level signal received by each shift register unit is a low level signal; the positive selection signal CHOF received by each shift register unit except the first shift register unit is a signal outputted by a previous shift register unit, and the first shift register unit receives a signal outputted by a first redundancy shift register unit as its positive selection signal CHOF thereof, and the positive selection signal CHOF received by the first redundancy shift register unit is an initial trigger signal STV; the reverse selection signal CHOB received by each shift register unit except the last shift register unit is a signal outputted by the next shift register unit, and the last shift register unit receives a signal outputted by a second redundancy shift register unit as its reverse selection signal CHOB thereof.

When the shift register including the shift register units according to the embodiments of the invention performs a reverse scanning, the first level signal received by each shift register unit is a low level signal, and the second level signal received by each shift register unit is a high level signal; the reverse selection signal CHOB received by each shift register unit except the last shift register unit is a signal outputted by a next shift register unit, the last shift register unit receives a signal outputted by the second redundancy shift register unit as the reverse selection signal CHOB thereof, and the reverse selection signal received by the second redundancy shift register unit is an initial trigger signal STV; and the positive selection signal CHOF received by each shift register unit except the first shift register unit is a signal outputted by a previous shift register unit, the first shift register unit receives the signal outputted by the first redundancy shift register unit as its positive selection signal CHOF thereof.

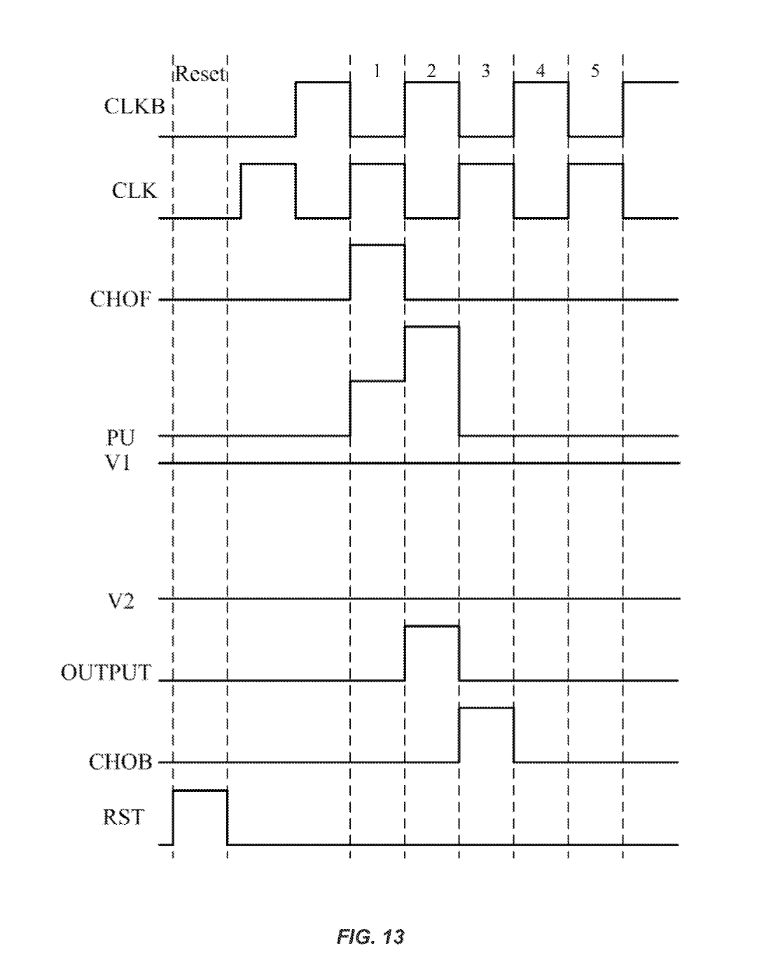

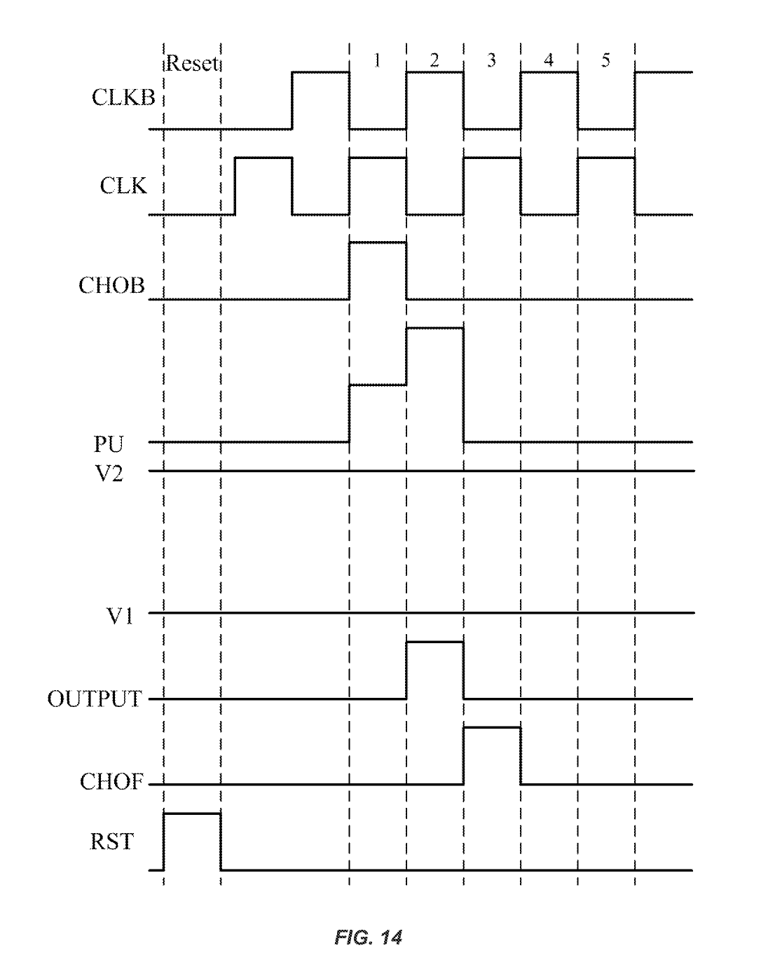

In order to further illustrate the shift register unit according to the embodiments of the invention, the working principle of the shift register unit provided in the embodiments of the invention is illustrated below with reference to time sequence diagrams shown in FIG. 13 and FIG. 14, wherein FIG. 13 is a working time sequence diagram of the shift register unit during a positive scanning period, and FIG. 14 is a working time sequence diagram of the shift register unit during a reverse scanning period.

As shown in FIG. 13, during positive scanning period, the first level signal V1 is a high level signal, the second level signal V2 is a low level signal, and a working time sequence of the shift register unit provided in the embodiments of the invention may be divided into 6 stages.

Reset stage: the reset signal RST is a high level signal, i.e., the signals of the gates of both the first transistor M1 and the fifth transistor M5 in the shift register unit shown in FIG. 10 are high level signals, so that both the first transistor M1 and the fifth transistor M5 are turned on, the signal of the output terminal OUTPUT of the shift register unit is the low voltage signal VGL due to the turn-on of the fifth transistor M5, and the pull-up node PU is connected with the output terminal OUTPUT of the shift register unit due to the turn-on of the first transistor M1, i.e., the signal of the pull-up node PU is the low voltage signal VGL; and similarly, the reset signal RST is a high level signal, i.e., the ninth transistor M9 and the tenth transistor M10 in the shift register unit shown in FIG. 12 are turned on, the level of the pull-up node PU is a low level due to the turn-on of the ninth transistor M9, and the level of the output terminal OUTPUT of the shift register unit is a low level due to the turn-on of the tenth transistor M10.

First stage: the clock signal CLK is a high level signal (logic high level), the clock blocking signal CLKB is a low level signal (logic low level), the positive selection signal CHOF is a high level signal, and the reverse selection signal CHOB is a low level signal. Referring to FIG. 8, the positive selection signal CHOF received by the gate of the third transistor M3 is a high level signal, the third transistor M3 is turned on, the signal of the pull-up node PU is the first level signal V1, i.e., a high level signal, the second capacitor C2 stores this high level signal, and the seventh transistor M7 is turned on, so that the shift register unit starts outputting the received clock blocking signal CLKB which is a low level signal at this stage, that is, the shift register unit outputs a low level signal at this stage. At this stage, the reverse selection signal CHOB received by the gate of the fourth transistor M4 is a low level signal, and the fourth transistor M4 is turned off; the sixth transistor M6 is turned on because the clock signal CLK is a high level signal, so that the signal of the output terminal OUTPUT of the shift register unit is a low voltage signal; and the second transistor M2 is turned on because the signal of the pull-up node PU is a high level signal, so that the signals of the gates of both the first transistor M1 and the fifth transistor M5 are low level signals, thus the first transistor M1 and the fifth transistor M5 are turned off.

Second stage: the clock signal CLK is a low level signal, the clock blocking signal CLKB is a high level signal, the positive selection signal CHOF is a low level signal, and the reverse selection signal CHOB is a low level signal. At this stage, the positive selection signal CHOF received by the gate of the third transistor M3 is a low level signal, so the third transistor M3 is turned off, but the signal of the pull-up node PU is kept as the high level signal due to the storage effect of the second capacitor C2, and the seventh transistor M7 is maintained turned on, so that the shift register unit outputs the received clock blocking signal CLKB which is a high level signal at this stage, that is, the shift register unit outputs a high level signal at this stage. At this stage, the reverse selection signal CHOB received by the gate of the fourth transistor M4 is the low level signal, and the fourth transistor M4 is turned off; because the clock signal CLK is a low level signal, the sixth transistor M6 is turned off; because the clock blocking signal CLKB is a high level signal, the signal of the first electrode of the second transistor M2 is a high level signal, meanwhile, because the signal of the pull-up node PU is a high level signal, the second transistor M2 is turned on, thus, the signal of the first electrode of the second transistor M2 is quickly changed into a low level signal, that is, the signals of the gates of both the first transistor M1 and the fifth transistor M5 are subjected to a process of being quickly changed from a high level signal to a low level signal, thus the first transistor M1 and the fifth transistor M5 will be turned on and then quickly turned off; although the output terminal OUTPUT of the shift register unit is connected with the port for providing the low voltage signal VGL due to the turn-on of the fifth transistor M5, the fifth transistor M5 will produce a weak pull-down effect on a high level of a gate line connected with the output terminal of the shift register unit due to the limitation of a channel width of the fifth transistor M5, that is, the turn-on of the fifth transistor M5 won't affect the signal outputted by the shift register unit, and the output terminal OUTPUT of the shift register unit will still output a high level signal; and the pull-up node PU is connected with the output terminal OUTPUT of the shift register unit due to the turn-on of the first transistor M1, and since the output terminal OUTPUT of the shift register unit outputs a high level signal, a pull-down effect on the potential of the pull-up node PU can be avoided. Meanwhile, due to the bootstrap effect, one terminal of the second capacitor C2, which is connected with the output terminal OUTPUT of the shift register unit, is changed from a low level in the first stage to a high level in the second stage, the potential of the pull-up node PU connected to the other terminal of the second capacitor C2 further rises.

Third stage: the clock signal CLK is a high level signal, the clock blocking signal CLKB is a low level signal, the positive selection signal CHOF is a low level signal, and the reverse selection signal CHOB is a high level signal. At this stage, the positive selection signal CHOF received by the gate of the third transistor M3 is a low level signal, the third transistor M3 is turned off, whereas the reverse selection signal CHOB received by the gate of the fourth transistor M4 is a high level signal, the fourth transistor M4 is turned on, so the signal of the pull-up node PU is the second level signal V2, i.e., a low level signal, and the second capacitor C2 stores this low level signal, and the seventh transistor M7 is turned off, so that the shift register unit does not output the received clock blocking signal CLKB any more; the clock signal CLK is a high level signal, the sixth transistor M6 is turned on, so that the signal of the output terminal OUTPUT of the shift register unit is a low voltage signal; and because the signal of the pull-up node PU is a low level signal, the second transistor M2 is turned off, meanwhile, because the clock blocking signal CLKB is a low level signal, the signals of the gates of both the first transistor M1 and the fifth transistor M5 are low voltage signals, therefore the first transistor M1 and the fifth transistor M5 are turned off.

Fourth stage: the clock signal CLK is a low level signal, the clock blocking signal CLKB is a high level signal, the positive selection signal CHOF is a low level signal, and the reverse selection signal CHOB is a low level signal. At this stage, the positive selection signal CHOF received by the gate of the third transistor M3 is a low level signal, the third transistor M3 is turned off, the reverse selection signal CHOB received by the gate of the fourth transistor M4 is a low level signal, the fourth transistor M4 is turned off; the signal of the pull-up node PU is still the low level signal due to the storage effect of the second capacitor C2, so the seventh transistor M7 is turned off, so that the shift register unit does not output the received clock blocking signal CLKB any more; because the clock signal CLK is a low level signal, the sixth transistor M6 is turned off; because the signal of the pull-up node PU is a low level signal, the second transistor M2 is turned off, meanwhile, because the clock blocking signal CLKB is a high level signal, the signals of the gates of both the first transistor M1 and the fifth transistor M5 are high level signals, so the first transistor M1 and the fifth transistor M5 are turned on; and the signal of the output terminal OUTPUT of the shift register unit is a low voltage signal due to turn-on of the fifth transistor M5, and the pull-up node PU is connected with the output terminal OUTPUT of the shift register unit due to turn-on of the first transistor M1, so that the signal of the pull-up node PU is a low voltage signal.

Fifth stage: the clock signal CLK is a high level signal, the clock blocking signal CLKB is a low level signal, the positive selection signal CHOF is a low level signal, and the reverse selection signal CHOB is a low level signal. At this stage, the positive selection signal CHOF received by the gate of the third transistor M3 is a low level signal, the third transistor M3 is turned off, the reverse selection signal CHOB received by the gate of the fourth transistor M4 is a low level signal, the fourth transistor M4 is turned off; the signal of the pull-up node PU is still the low level signal due to the storage effect of the second capacitor C2, and the seventh transistor M7 is turned off, so that the shift register unit does not output the received clock blocking signal CLKB any more; because the clock signal CLK is a high level signal, the sixth transistor M6 is turned on, so that the signal of the output terminal OUTPUT of the shift register unit is a low voltage signal; because the signal of the pull-up node PU is a low level signal, the second transistor M2 is turned off, meanwhile, because the clock blocking signal CLKB is a low level signal, the signals of the gates of both the first transistor M1 and the fifth transistor M5 are low level signals, therefore the first transistor M1 and the fifth transistor M5 are turned off.

Thereafter, the 4th stage and the 5th stage are successively repeated till the positive selection signal CHOF received by the shift register unit provided in the embodiments of the invention becomes a high level signal, and then the 1st to 5th stages are re-executed; or the 4th stage and the 5th stage are successively repeated till the reset signal RST received by the shift register unit provided in the embodiments of the invention becomes a high level signal, and then the reset stage is executed. Wherein, the 1st stage and the 2nd stage are within a working time of the shift register unit, i.e., the time when the gate line connected with the output terminal of the shift register unit is selected, whereas the 3rd, 4th and 5th stages and the reset stage are within a non-working time of the shift register unit, i.e., the time when the gate line connected with the output terminal of the shift register unit is not selected.

As shown in FIG. 14, during a reverse scanning period, the first level signal V1 is a low level signal, the second level signal V2 is a high level signal, and a working time sequence of the shift register unit provided in the embodiments of the invention may be divided into 6 stages.

Reset stage: the reset signal RST is a high level signal, i.e., the signals of the gates of both the first transistor M1 and the fifth transistor M5 in the shift register unit shown in FIG. 10 are high level signals, so that both the first transistor M1 and the fifth transistor M5 are turned on, the signal of the output terminal OUTPUT of the shift register unit is a low voltage signal VGL due to turn-on of the fifth transistor M5, and the pull-up node PU is connected with the output terminal OUTPUT of the shift register unit due to turn-on of the first transistor M1, i.e., the signal of the pull-up node PU is the low voltage signal VGL; and similarly, the reset signal RST is a high level signal, i.e., the ninth transistor M9 and the tenth transistor M10 in the shift register unit shown in FIG. 12 are turned on, the level of the pull-up node PU is a low level due to turn-on of the ninth transistor M9, and the level of the output terminal OUTPUT of the shift register unit is a low level due to turn-on of the tenth transistor M10.

First stage: the clock signal CLK is a high level signal, the clock blocking signal CLKB is a low level signal, the reverse selection signal CHOB is a high level signal, and the positive selection signal CHOF is a low level signal. At this stage, still referring to FIG. 8, the reverse selection signal CHOB received by the gate of the fourth transistor M4 is a high level signal, the fourth transistor M4 is turned on, so the signal of the pull-up node PU is the second level signal V2, i.e., a high level signal, and the second capacitor C2 stores this high level signal, and the seventh transistor M7 is turned on, so that the shift register unit starts outputting the received clock blocking signal CLKB which is a low level signal at this stage, that is, the shift register unit outputs a low level signal at this stage. At this stage, the positive selection signal CHOF received by the gate of the third transistor M3 is a low level signal, and the third transistor M3 is turned off; the clock signal CLK is a high level signal, and the sixth transistor M6 is turned on, so that the signal of the output terminal of the shift register unit is a low voltage signal; and the second transistor M2 is turned on because the signal of the pull-up node PU is a high level signal, so the signals of the gates of both the first transistor M1 and the fifth transistor M5 are low voltage signals, and the first transistor M1 and the fifth transistor M5 are turned off.

Second stage: the clock signal CLK is a low level signal, the clock blocking signal CLKB is a high level signal, the positive selection signal CHOF is a low level signal, and the reverse selection signal CHOB is a low level signal. At this stage, the reverse selection signal CHOB received by the gate of the fourth transistor M4 is a low level signal, so the fourth transistor M4 is turned off, but the signal of the pull-up node PU is kept as the high level signal due to the storage effect of the second capacitor C2, and the seventh transistor M7 is maintained turned on, so that the shift register unit outputs the received clock blocking signal CLKB which is a high level signal at this stage, that is, the shift register unit outputs a high level signal at this stage. At this stage, the positive selection signal CHOF received by the gate of the third transistor M3 is a low level signal, so the third transistor M3 is turned off; because the clock signal CLK is a low level signal, the sixth transistor M6 is turned off; because the clock blocking signal CLKB is a high level signal, the signal of the first electrode of the second transistor M2 is a high level signal, meanwhile, because the signal of the pull-up node PU is a high level signal, the second transistor M2 is turned on, thus, the signal of the first electrode of the second transistor M2 is quickly changed into a low level signal, that is, the signals of the gates of both the first transistor M1 and the fifth transistor M5 are subjected to a process of being quickly changed from a high level signal to a low level signal, and the first transistor M1 and the fifth transistor M5 will be turned on and then quickly turned off; although the output terminal of the shift register unit is connected with the port for providing the low voltage signal VGL due to turn-on of the fifth transistor M5, the fifth transistor M5 will produce a weak pull-down effect on a high potential of the gate line connected with the output terminal of the shift register unit due to the limitation of the channel width of the fifth transistor M5, that is, turn-on of the fifth transistor M5 will not affect the signal outputted by the shift register unit, and the output terminal OUTPUT of the shift register unit will still output a high level signal; and the pull-up node PU is connected with the output terminal OUTPUT of the shift register unit due to turn-on of the first transistor M1, and since the output terminal OUTPUT of the shift register unit outputs a high level signal, so a pull-down effect on the potential of the pull-up node PU can be avoided. Meanwhile, due to a bootstrap effect, one terminal of the second capacitor C2, which is connected with the output terminal OUTPUT of the shift register unit, is changed from a low level in the first stage to a high level in the second stage, the potential of the pull-up node PU further rises.

Third stage: the clock signal CLK is a high level signal, the clock blocking signal CLKB is a low level signal, the positive selection signal CHOF is a high level signal, and the reverse selection signal CHOB is a low level signal. At this stage, the positive selection signal CHOF received by the gate of the third transistor M3 is a high level signal, the third transistor M3 is turned on, whereas the reverse selection signal CHOB received by the gate of the fourth transistor M4 is a low level signal, the fourth transistor M4 is turned off, the signal of the pull-up node PU is the first level signal V1, i.e., a low level signal, the second capacitor C2 stores this low level signal, and the seventh transistor M7 is turned off, so that the shift register unit does not output the received clock blocking signal CLKB any more; the clock signal CLK is a high level signal, and the sixth transistor M6 is turned on, so that the signal of the output terminal OUTPUT of the shift register unit is a low voltage signal; and because the signal of the pull-up node PU is a low level signal, the second transistor M2 is turned off, meanwhile, because the clock blocking signal CLKB is a low level signal, the signals of the gates of both the first transistor M1 and the fifth transistor M5 are low level signals, and the first transistor M1 and the fifth transistor M5 are turned off.

Fourth stage: the clock signal CLK is a low level signal, the clock blocking signal CLKB is a high level signal, the positive selection signal CHOF is a low level signal, and the reverse selection signal CHOB is a low level signal. At this stage, the positive selection signal CHOF received by the gate of the third transistor M3 is a low level signal, the third transistor M3 is turned off, and the reverse selection signal CHOB received by the gate of the fourth transistor M4 is a low level signal, the fourth transistor M4 is turned off, and the signal of the pull-up node PU is still the low level signal due to the storage effect of the second capacitor C2, and the seventh transistor M7 is turned off, so that the shift register unit does not output the received clock blocking signal CLKB any more; because the clock signal CLK is a low level signal, the sixth transistor M6 is turned off; because the signal of the pull-up node PU is a low level signal, the second transistor M2 is turned off, meanwhile, because the clock blocking signal CLKB is a high level signal, the signals of the gates of both the first transistor M1 and the fifth transistor M5 are high level signals, and the first transistor M1 and the fifth transistor M5 are turned on; and the signal of the output terminal OUTPUT of the shift register unit is a low voltage signal due to the turn-on of the fifth transistor M5, and the pull-up node PU is connected with the output terminal OUTPUT of the shift register unit due to the turn-on of the first transistor M1, so that the signal of the pull-up node PU is a low voltage signal.

Fifth stage: the clock signal CLK is a high level signal, the clock blocking signal CLKB is a low level signal, the positive selection signal CHOF is a low level signal, and the reverse selection signal CHOB is a low level signal. At this stage, the positive selection signal CHOF received by the gate of the third transistor M3 is a low level signal, the third transistor M3 is turned off, the reverse selection signal CHOB received by the gate of the fourth transistor M4 is a low level signal, the fourth transistor M4 is turned off, the signal of the pull-up node PU is still the low level signal due to a storage effect of the second capacitor C2, and the seventh transistor M7 is turned off, so that the shift register unit does not output the received clock blocking signal CLKB any more; because the clock signal CLK is a high level signal, the sixth transistor M6 is turned on, so that the signal of the output terminal OUTPUT of the shift register unit is a low voltage signal; because the signal of the pull-up node PU is a low level signal, the second transistor M2 is turned off, meanwhile, because the clock blocking signal CLKB is a low level signal, therefore the signals of the gates of both the first transistor M1 and the fifth transistor M5 are low level signals, and the first transistor M1 and the fifth transistor M5 are turned off.

Thereafter, the 4th stage and the 5th stage are successively repeated till the positive selection signal CHOF received by the shift register unit provided in the embodiments of the invention becomes a high level signal, and then the 1st to 5th stages are re-executed; or the 4th stage and the 5th stage are successively repeated till the reset signal RST received by the shift register unit provided in the embodiments of the invention becomes a high level signal, and then the reset stage is executed. Wherein the 1st stage and the 2nd stage are within a working time of the shift register unit, i.e., the time when the gate line connected with the output terminal of the shift register unit is selected, whereas the 3rd, 4th and 5th stages and the reset stage are within a non-working time of the shift register unit, i.e., the time when the gate line connected with the output terminal of the shift register unit is not selected.

Another embodiment of the invention further provides a display panel, including the shift register unit provided in any above embodiments of the invention.

Another embodiment of the invention further provides a display device, including any display panel provided in the embodiments of the invention.

The sequence of the above-mentioned embodiments of the invention is merely for description, and does not represent merits priority of the embodiments.

Evidently those skilled in the art can make various modifications and variations to the invention without departing from the essence and scope of the invention. Thus the invention is also intended to encompass these modifications and variations thereto so long as the modifications and variations come into the scope of the claims appended to the invention and their equivalents.

What is claimed is:

1. A shift register unit comprising a driving module, an output module, a first transistor and a second transistor,
wherein a first port of the driving module receives a positive selection signal, a second port of the driving module receives a first level signal, a third port of the driving module receives a reverse selection signal, a fourth port of the driving module receives a second level signal, a fifth port of the driving module receives a low voltage signal, a sixth port of the driving module is connected with a gate of the first transistor and a first electrode of the second transistor, a seventh port of the driving module is connected with a third port of the output module, an eighth port of the driving module is connected with a first electrode of the first transistor, a gate of the second transistor and a first port of the output module at a pull-up node, a ninth port of the driving module receives a clock blocking signal, a tenth port of the driving module receives a clock signal, a second electrode of the first transistor is connected with the third port of the output module, a second electrode of the second transistor receives the low voltage signal, a second port of the output module receives the clock blocking signal, and the third port of the output module serves as an output terminal of the shift register unit;
the driving module is configured to output the first level signal through the eighth port when the positive selection signal is at a logic high level and the clock blocking signal is at a logic low level, and to output the second level signal through the eighth port when the reverse selection signal is at the logic high level and the clock blocking signal is at the logic low level, and to output the low voltage signal through the seventh port when the clock signal is at the logic high level, and to output the clock blocking signal through the sixth port, and to output the low voltage signal through the seventh port when the first electrode of the second transistor is at the logic high level;
the output module is configured to output the clock blocking signal through the third port of the output module when the pull-up node is at a turn-on level and stops outputting the clock blocking signal when the pull-up node is at a turn-off level;
the first transistor is configured to connect the pull-up node with the output end of the shift register unit when the first electrode of the second transistor is at the logic high level and to disconnect the pull-up node from the output end of the shift register unit when the first electrode of the second transistor is at the logic low level; and
the second transistor is configured to control the first electrode of the second transistor to be the low voltage signal when the pull-up node is at the turn-on level and to be turned off when the pull-up node is at the turn-off level.

2. The shift register unit of claim 1, wherein the driving module comprises a first driving cell, a second driving cell and a third driving cell, wherein:
a first port of the first driving cell is connected with the first port of the driving module, a second port of the first driving cell is connected with the second port of the driving module, a third port of the first driving cell and a third port of the second driving cell are connected with the eighth port of the driving module, a first port of the second driving cell is connected with the third port of the driving module, a second port of the second driving cell is connected with the fourth port of the driving module, a first port of the third driving cell is connected with the ninth port of the driving module, a second port of the third driving cell is connected with the tenth port of the driving module, a third port of the third driving cell is connected with the seventh port of the driving module, a fourth port of the third driving cell is connected with the fifth port of the driving module, and a fifth port of the third driving cell is connected with the sixth port of the driving module;
the first driving cell is configured to output the first level signal through the third port of the first driving cell when the positive selection signal is at the logic high level;
the second driving cell is configured to output the second level signal through the third port of the second driving cell when the reverse selection signal is at the logic high level; and
the third driving cell is configured to output the low voltage signal through the third port of the third driving cell when the clock signal is at the logic high level and to output the clock blocking signal through the fifth port of the third driving cell, and to output the low voltage signal through the third port of the third driving cell when the first electrode of the second transistor is at the logic high level.

3. The shift register unit of claim 2, wherein the first driving cell comprises a third transistor, wherein:
a gate of the third transistor is connected with the first port of the first driving cell, a first electrode of the third transistor is connected with the second port of the first driving cell, and a second electrode of the third transistor is connected with the third port of the first driving cell; and
the third transistor is configured to be turned on when the positive selection signal is at the logic high level 1 and to be turned off when the positive selection signal is at the logic low level.

4. The shift register unit of claim 2, wherein the second driving cell comprises a fourth transistor, wherein:
a gate of the fourth transistor is connected with the first port of the second driving cell, a first electrode of the fourth transistor is connected with the second port of the second driving cell, and a second electrode of the fourth transistor is connected with the third port of the second driving cell; and
the fourth transistor is configured to be turned on when the reverse selection signal is at the logic high level and to be turned off when the reverse selection signal is at the logic low level.

5. The shift register unit of claim 2, wherein the third driving cell comprises a first capacitor, a fifth transistor and a sixth transistor, wherein:
one terminal of the first capacitor is connected with the first port of the third driving cell, the other terminal of the first capacitor and a gate of the fifth transistor are connected with the fifth port of the third driving cell, a first electrode of the fifth transistor and a first electrode of the sixth transistor are connected with the third port of the third driving cell, a second electrode of the fifth transistor and a second electrode of the sixth transistor are connected with the fourth port of the third driving cell, and a gate of the sixth transistor is connected with the second port of the third driving cell;
the first capacitor is configured to couple the received clock blocking signal to the first electrode of the second transistor;
the fifth transistor is configured to be turned on when the first electrode of the second transistor is at the logic high level and to be turned off when the first electrode of the second transistor is at the logic low level; and
the sixth transistor is configured to be turned on when the clock signal is at the logic high level and to be turned off when the clock signal is at the logic low level.

6. The shift register unit of claim 1, wherein the output module comprises a second capacitor and a seventh transistor,
one terminal of the second capacitor and a gate of the seventh transistor are connected with the first port of the output module, the other terminal of the second capacitor and a second electrode of the seventh transistor are connected with the third port of the output module, and a first electrode of the seventh transistor is connected with the second port of the output module;
the second capacitor is configured to store a signal of the pull-up node; and
the seventh transistor is configured to be turned on when the pull-up node is at the logic high level and to be turned off when the pull-up node is at the logic low level.

7. The shift register unit of claim 1, further comprising a first reset module, wherein a first port of the first reset module receives a reset signal, and a second port of the first reset module is connected with the first electrode of the second transistor; and
the first reset module is configured to, when the reset signal is at the logic high level, output the high level signal through the second port of the first reset module.

8. The shift register unit of claim 7, wherein the first reset module comprises an eighth transistor having a gate and a first electrode connected with the first port of the first reset module, and a second electrode connected with the second port of the first reset module; and
the eighth transistor is configured to be turned on when the reset signal is at the logic high level and to be turned off when the reset signal is at the logic low level.

9. The shift register unit of claim 1, further comprising a second reset module, wherein a first port of the second reset module is connected with the pull-up node, a second port of the second reset module receives the low voltage signal, a third port of the second reset module is connected with the output terminal of the shift register unit, and a fourth port of the second reset module receives a reset signal; and
the second reset module is configured to output the low voltage signal through the first port and the third port of the second reset module respectively when the reset signal is at the logic high level.

10. The shift register unit of claim 9, wherein the second reset module comprises a ninth transistor and a tenth transistor,
gates of the respective ninth transistor and the tenth transistor are connected with the fourth port of the second reset module, a first electrode of the ninth transistor is connected with the first port of the second reset module, second electrodes of the respective ninth transistor and the tenth transistor are connected with the second port of the second reset module, and a first electrode of the tenth transistor is connected with the third port of the second reset module;
the ninth transistor is configured to be turned on when the reset signal is at the logic high level and to be turned off when the reset signal is at the logic low level; and
the tenth transistor is configured to be turned on when the reset signal is at the logic high level signal and to be turned off when the reset signal is at the logic low level.

11. A display panel comprising a shift register unit comprising a driving module, an output module, a first transistor and a second transistor, wherein:
a first port of the driving module receives a positive selection signal, a second port of the driving module receives a first level signal, a third port of the driving module receives a reverse selection signal, a fourth port of the driving module receives a second level signal, a fifth port of the driving module receives a low voltage signal, a sixth port of the driving module is connected with a gate of the first transistor and a first electrode of the second transistor, a seventh port of the driving module is connected with a third port of the output module, an eighth port of the driving module is connected with a first electrode of the first transistor, a gate of the second transistor and a first port of the output module at a connecting node being a pull-up node, a ninth port of the driving module receives a clock blocking signal, a tenth port of the driving module receives a clock signal, a second electrode of the first transistor is connected with the third port of the output module, a second electrode of the second transistor receives the low voltage signal, a second port of the output module receives the clock blocking signal, and the third port of the output module serves as an output terminal of the shift register unit;
the driving module is configured to output the first level signal through the eighth port when the positive selection signal is a logic high level and the clock blocking signal is at a logic low level, and to output the second level signal through the eighth port when the reverse selection signal is at the logic high level signal and the clock blocking signal is at the logic low level, and to output the low voltage signal through the seventh port when the clock signal is at the logic high level signal, and to output the clock blocking signal through the sixth port, and to output the low voltage signal through the seventh port when the first electrode of the second transistor is at the logic high level;
the output module is configured to output the clock blocking signal through the third port of the output module when the pull-up node is at a turn-on level, and stops outputting the clock blocking signal when the pull-up node is at a turn-off level;
the first transistor is configured to connect the pull-up node with the output terminal of the shift register unit when a signal of the first electrode of the second transistor is a high level signal, and to disconnect the pull-up node from the output terminal of the shift register unit when a potential of the first electrode of the second transistor is low; and
the second transistor is configured to control a signal of the first electrode of the second transistor to be the low voltage signal when the pull-up node is at the turn-on level, and to be turned off when the pull-up node is at the turn-off level.

12. The display panel of claim 11, wherein the driving module comprises a first driving cell, a second driving cell and a third driving cell,
a first port of the first driving cell is connected with the first port of the driving module, a second port of the first driving cell is connected with the second port of the driving module, a third port of the first driving cell and a third port of the second driving cell are connected with the eighth port of the driving module, a first port of the second driving cell is connected with the third port of the driving module, a second port of the second driving cell is connected with the fourth port of the driving module, a first port of the third driving cell is connected with the ninth port of the driving module, a second port of the third driving cell is connected with the tenth port of the driving module, a third port of the third driving cell is connected with the seventh port of the driving module, a fourth port of the third driving cell is connected with the fifth port of the driving module, and a fifth port of the third driving cell is connected with the sixth port of the driving module;
the first driving cell is configured to output the first level signal through the third port of the first driving cell when the positive selection signal is at the logic high level;
the second driving cell is configured to output the second level signal through the third port of the second driving cell when the reverse selection signal is at the logic high level; and
the third driving cell is configured to output the low voltage signal through the third port of the third driving cell when the clock signal is at the logic high level, and to output the clock blocking signal through the fifth port of the third driving cell, and to output the low voltage signal through the third port of the third driving cell when the first electrode of the second transistor is at the logic high level.

13. The display panel of claim 12, wherein the first driving cell comprises a third transistor,
a gate of the third transistor is connected with the first port of the first driving cell, a first electrode of the third transistor is connected with the second port of the first driving cell, and a second electrode of the third transistor is connected with the third port of the first driving cell; and
the third transistor is configured to be turned on when the positive selection signal is at the logic high level and to be turned off when the positive selection signal is at the logic low level.

14. The display panel of claim 12, wherein the second driving cell comprises a fourth transistor,
a gate of the fourth transistor is connected with the first port of the second driving cell, a first electrode of the fourth transistor is connected with the second port of the second driving cell, and a second electrode of the fourth transistor is connected with the third port of the second driving cell; and
the fourth transistor is configured to be turned on when the reverse selection signal is at the logic high level and to be turned off when the reverse selection signal is at the logic low level.

15. The display panel of claim 12, wherein the third driving cell comprises a first capacitor, a fifth transistor and a sixth transistor,
one terminal of the first capacitor is connected with the first port of the third driving cell, the other terminal of the first capacitor and a gate of the fifth transistor are connected with the fifth port of the third driving cell, a first electrode of the fifth transistor and a first electrode of the sixth transistor are connected with the third port of the third driving cell, a second electrode of the fifth transistor and a second electrode of the sixth transistor are connected with the fourth port of the third driving cell, and a gate of the sixth transistor is connected with the second port of the third driving cell;
the first capacitor is configured to couple the received clock blocking signal to the first electrode of the second transistor;
the fifth transistor is configured to be turned on when the first electrode of the second transistor is at the logic high level and to be turned off when the first electrode of the second transistor is at the logic low level; and
the sixth transistor is configured to be turned on when the clock signal is at the logic high level and to be turned off when the clock signal is at the logic low level.

16. The display panel of claim 11, wherein the output module comprises a second capacitor and a seventh transistor,
one terminal of the second capacitor and a gate of the seventh transistor are connected with the first port of the output module, the other terminal of the second capacitor and a second electrode of the seventh transistor are connected with the third port of the output module, and a first electrode of the seventh transistor is connected with the second port of the output module;
the second capacitor is configured to store a signal of the pull-up node; and
the seventh transistor is configured to be turned on when the pull-up node is at the turn-on level and to be turned off when the pull-up node is at the turn-off level.

17. The display panel of claim 11, wherein the shift register unit further comprises a first reset module, a first port of the first reset module receives a reset signal, and a second port of the first reset module is connected with the first electrode of the second transistor; and
the first reset module is configured to, when the reset signal is at the logic high level, output the high level signal through the second port of the first reset module.

18. The display panel of claim 17, wherein the first reset module comprises an eighth transistor including a gate and a first electrode connected with the first port of the first reset module, and a second electrode connected with the second port of the first reset module; and
the eighth transistor is configured to be turned on when the reset signal is at the logic high level and to be turned off when the reset signal is at the logic low level.

19. The display panel of claim 11, wherein the shift register unit further comprises a second reset module having a first port connected with the pull-up node, a second port for receiving the low voltage signal, a third port connected with the output terminal of the shift register unit, and a fourth port for receiving a reset signal; and
the second reset module is configured to output the low voltage signal through the first port and the third port of the second reset module, respectively, when the reset signal is at the logic high level.

20. The display panel of claim 19, wherein the second reset module comprises a ninth transistor and a tenth transistor,
gates of the respective ninth transistor and tenth transistor are connected with the fourth port of the second reset module, a first electrode of the ninth transistor is connected with the first port of the second reset module, second electrodes of the respective ninth transistor and tenth transistor are connected with the second port of the second reset module, and a first electrode of the tenth transistor is connected with the third port of the second reset module;
the ninth transistor is configured to be turned on when the reset signal is at the logic high level and to be turned off when the reset signal is at the logic low level; and
the tenth transistor is configured to be turned on when the reset signal is at the logic high level and to be turned off when the reset signal is at the logic low level.
